(19) United States
(12) Patent Application Publication
(10) Pub. No.: US 2024/0364227 A1
(43) Pub. Date: Oct. 31, 2024

(54) SWITCHED-MODE POWER CONVERTER

(71) Applicant: SHANGHAI BRIGHT POWER SEMICONDUCTOR CO., LTD., Shanghai (CN)

(72) Inventors: Yanmei GUO, Shanghai (CN); Yue ZHENG, Shanghai (CN); Jianpei ZHU, Shanghai (CN)

(21) Appl. No.: 18/646,235

(22) Filed: Apr. 25, 2024

(30) Foreign Application Priority Data
Apr. 28, 2023 (CN) 202321021707.1

(51) Int. Cl. H02M 3/335; H01L 23/31; H01L 23/495

(52) U.S. Cl. CPC H02M 3/33592; H01L 23/3107; H01L 23/4952; H01L 23/49575; H01L 28/10

(57) ABSTRACT

The present invention provides a switched-mode power converter. A control circuit in the switched-mode power converter includes first and second control chips and a magnetic coupling chip coupled to both the former two. The magnetic coupling chip provides a galvanically isolated communication link between the first control chip and the second control chip. With the aid of the second control chip and the magnetic coupling chip, the control circuit can provide a feedback signal to the first control chip and thereby act on turn-on and turn-off of a switching device in the switching circuit. In this way, desirable output and isolation performance can be achieved. Since the first control chip, the second control chip and the magnetic coupling chip can be integrated at a high degree of integration, the switched-mode power converter can have a high degree of integration, reduced size and lower cost.

### CROSS-REFERENCES TO RELATED APPLICATION

This application claims the priority of Chinese patent application number 202321021707.1, filed on Apr. 28, 2023, the entire contents of which are incorporated herein by reference.

### TECHNICAL FIELD

The present invention relates to the field of power supply technology and, in particular, to a switched-mode power converter.

### BACKGROUND

Switched-mode power converters can provide a constant voltage or current output over a load range and feature a stable structure, high efficiency and diverse control modes. As the consumer electronics market is rapidly growing, switched-mode power converters have found extensive use.

Some switched-mode power converters, such as isolated flyback power converters, adopt isolated communication and usually include a switching circuit and a control circuit. The switching circuit utilizes an element capable of galvanic isolation for energy transfer (e.g., a high-frequency transformer). The switching circuit includes a switching device coupled to an input terminal of the energy transfer element and can be turned on and off to convert an input voltage into an output voltage for driving a load. The control circuit senses the output voltage, transfers a corresponding feedback signal to the input terminal of the energy transfer element in a galvanically isolated manner, and forms a control signal for the switching device.

A major challenge that switched-mode power converters are faced with is how to achieve a higher degree of integration, a reduced device size and lower cost while not compromising performance and isolation capabilities.

### SUMMARY

The present invention provides a switched-mode power converter including a first control chip, a second control chip and a magnetic coupling chip, which achieve control of a switching circuit and provide a communication link capable of galvanic isolation. This is helpful in increasing a degree of integration of the switched-mode power converter and reducing its size and cost.

The switched-mode power converter provided in the present invention includes a switching circuit and a control circuit. The switching circuit includes a switching device for converting an input voltage into an output voltage by turning on and off the switching device. The control circuit includes a first control chip, a second control chip and a magnetic coupling chip. The first control chip is coupled to a control terminal of the switching circuit, and the second control chip is coupled to an output terminal of the switching circuit. The magnetic coupling chip is coupled to both the first and second control chips, and is configured to provide a galvanically isolated communication link between the first and the second control chips.

Optionally, the magnetic coupling chip may be integrated, together with at least one of the first and second control chips, into an integrated circuit (IC) package.

Optionally, the first control chip, the second control chip and the magnetic coupling chip may be integrated into the IC package.

Optionally, in addition to the first control chip, the second control chip and the magnetic coupling chip, the IC package may further include a lead frame and an encapsulation body. The lead frame may support the first control chip, the second control chip and the magnetic coupling chip and include a plurality of pins, some of which are coupled to the first control chip, and the others of which are coupled to the second control chip. The first control chip may be coupled to the magnetic coupling chip by first metal bond wires, and the second control chip to the magnetic coupling chip by second metal bond wires. The encapsulation body may cover the first control chip, the second control chip, the magnetic coupling chip and part of the lead frame, with the plurality of pins being exposed.

Optionally, the first control chip and the magnetic coupling chip may be integrated into the IC package, and the second control chip may be integrated into another IC package.

Optionally, the second control chip and the magnetic coupling chip may be integrated into the IC package, and the first control chip may be integrated into another IC package.

Optionally, the magnetic coupling chip may include a semiconductor substrate and first and second coil conductors both provided on the semiconductor substrate, the first and second coil conductors providing an electromagnetic inductive communication link therebetween, the first coil conductor coupled to the first control chip, the second coil conductor coupled to the second control chip.

Optionally, the first and second coil conductors may be located in planes at different heights above the semiconductor substrate and spaced apart by an insulating layer disposed therebetween.

Optionally, the first and second coil conductors may be located in a single plane above the semiconductor substrate.

Optionally, the second control chip may sense the output voltage of the switching circuit and be based on the output voltage to control the second control chip to send a control signal to the first control chip, wherein the control signal is sent to the first control chip via the magnetic coupling chip.

Optionally, the control signal may be in the form of short pulses.

Optionally, the switching circuit may include a high-frequency transformer for energy transfer, wherein the first control chip is coupled to a primary-side input terminal of the high-frequency transformer by the switching device.

In the switched-mode power converter of the present invention, the control circuit includes the first control chip, the second control chip and the magnetic coupling chip coupled to both the first and second control chips. The magnetic coupling chip provides a galvanically isolated communication link between the first control chip and the second control chip. With the aid of the second control chip and the magnetic coupling chip, the control circuit can provide a feedback signal to the first control chip and thereby act on turn-on and turn-off of the switching device in the switching circuit. In this way, desirable output and isolation performance can be achieved. Since the first control chip, the second control chip and the magnetic coupling chip can be integrated at a high degree of integration, the switched-mode power converter can have a high degree of integration, reduced size and lower cost.

### BRIEF DESCRIPTION OF THE DRAWINGS

FIG. 1 is a schematic circuit diagram of a switched-mode power converter according to an embodiment of the present invention.

FIG. 2 schematically illustrates communication between first and second control chips according to an embodiment of the present invention.

FIG. 3 schematically illustrates communication between first and second control chips according to another embodiment of the present invention.

FIG. 4 is a schematic cross-sectional view of a magnetic coupling chip according to an embodiment of the present invention.

FIG. 5 schematically illustrates short pulses according to an embodiment of the present invention.

FIG. 6 schematically illustrates wiring of a control circuit consisting of one IC package according to an embodiment of the present invention.

FIG. 7 schematically illustrates wiring of a lead frame, a first control chip, a second control chip and a magnetic coupling chip in the IC package of FIG. 6.

FIG. 8 schematically illustrates wiring of a control circuit consisting of two IC packages according to another embodiment of the present invention.

FIG. 9 schematically illustrates wiring of a control circuit consisting of two IC packages according to yet another embodiment of the present invention.

### DETAILED DESCRIPTION

Switched-mode power converters constructed in accordance with specific embodiments of the present invention will be described in greater detail below with reference to the accompanying drawings. From the following description, advantages and features of the present invention will become more apparent. Note that the figures are provided in a very simplified form not necessarily drawn to exact scale and for the only purpose of facilitating easy and clear description of the embodiments disclosed herein. The embodiments of the present invention should not be construed as being limited to the particular shapes of the regions illustrated in the figures. For the sake of clarity, throughout the figures that help illustrate the embodiments disclosed herein, like elements are in principle labeled with like reference numbers, and repeated descriptions thereof are omitted. As used herein, the terms “first”, “second” and the like may be used to distinguish between similar elements without necessarily implying any particular ordinal or chronological sequence. It is to be understood that the terms so used are interchangeable, as appropriate. It would be appreciated that spatially relative terms are intended to encompass different orientations of the device in use or operation in addition to the orientation depicted in the figures. For example, if the device in the figures is inverted or otherwise oriented (e.g., rotated), the exemplary term “over” can encompass an orientation of “under” and other orientations.

Embodiments of the present invention relate to a switched-mode power converter capable of providing a galvanically isolated communication link using a magnetic coupling chip, which can help the switched-mode power converter achieve a higher degree of integration, a reduced device size and lower cost provide while not compromising performance and isolation capabilities. The switched-mode power converter is suited to various topologies, including but not limited to, synchronous flyback, isolated flyback, isolated synchronous flyback, buck, forward, half-bridge and full-bridge.

FIG. 1 is a schematic circuit diagram of a switched-mode power converter according to an embodiment of the present invention. Referring to FIG. 1, in one example, the switched-mode power converter includes a switching circuit 10 and a control circuit 20. The switching circuit 10 may be an isolated or non-isolated AC/DC converter. Alternatively, the switching circuit 10 may be an isolated or non-isolated DC/DC converter.

In the example of FIG. 1, the switched-mode power converter is of an isolated flyback topology. The switching circuit 10 includes an energy transfer element capable of galvanic isolation (shown as a high-frequency transformer 13), a primary-side circuit 11 and a secondary-side circuit 12. The primary-side circuit 11 is coupled to an input terminal of the energy transfer element, and the secondary-side circuit 12 is coupled to an output terminal of the energy transfer element. By virtue of the high-frequency transformer 13, the switching circuit 10 provides galvanic isolation between the primary-side circuit 11 and the secondary-side circuit 12.

The primary-side circuit 11 receives an AC input from an input terminal of the switching circuit 10 (labelled as “AC” in FIG. 1) and includes: diodes D1, D2, D3, D4, which form a rectifier bridge circuit; a filter capacitor C1; a resistor R1, a capacitor C2 and a diode D5, which form an absorption circuit for reducing voltage spikes caused by leakage inductance; a switching device MI coupled to an input terminal of the high-frequency transformer 13; and dotted terminals S1 and S2 of the high-frequency transformer 13. The secondary-side circuit 12 includes an output capacitor C3, two terminals of the output capacitor C3 are both coupled to a load; a synchronous rectifier switch M2 coupled to an output terminal of the high-frequency transformer 13; and voltage-dividing resistors R2 and R3. A ground terminal of the primary-side circuit 11 and a ground terminal of the secondary-side circuit 12 are not commonly grounded. The switching device MI is, for example, an enhanced n-channel MOS transistor.

The switching circuit 10 converts an input voltage (e.g., an AC voltage) into an output voltage Vo through turning on and off the switching device M1, thereby achieving energy transfer.

According to embodiments of the present invention, in the switched-mode power converter, the control circuit 20 can control elements in the switching circuit 10 and the secondary-side circuit 10 and can form a feedback loop between primary-side circuit 11 and the secondary-side circuit 12. The control circuit 20 includes a first control chip 21, a second control chip 22 and a magnetic coupling chip 23. The first control chip 21 is coupled to a control terminal of the switching device M1. The second control chip 22 is coupled to an output terminal of the switching circuit 10. The magnetic coupling chip 23 is coupled to both the first control chip 21 and the second control chip 22 and forms a galvanically isolated communication link (e.g., one-way or two-way) between the first control chip 21 and the second control chip 22. The magnetic coupling chip 23 is an integrated chip with a degree of integration, which is helpful in increasing the degree of integration of the control circuit 20 and the switched-mode power converter.

The control circuit 20 may form the feedback loop between the primary-side circuit 11 and the secondary-side circuit 12 according to any suitable method known in the art. For example, the control circuit 20 may utilize a control method based on output voltage ripple or an average output voltage known in the art to sense the output voltage Vo (e.g., by sampling a divided voltage of the output voltage Vo) and form a control signal which is applied to the control terminal of the switching device M1.

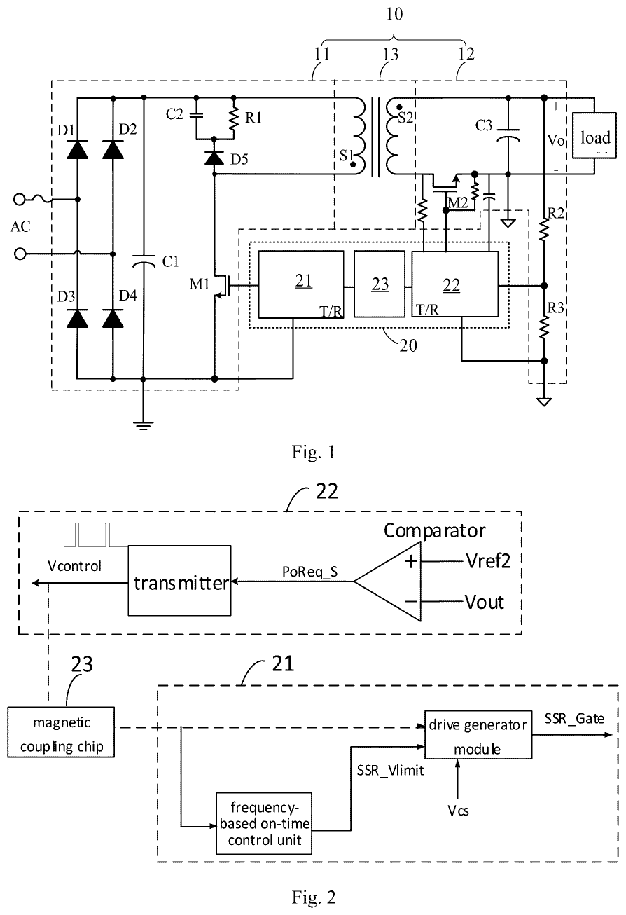

FIG. 2 schematically illustrates communication between the first and second control chips according to an embodiment of the present invention. Referring to

FIG. 2, in one example, the control circuit 20 may employ a control method based on output voltage ripple. In this embodiment, the second control chip 22 acquires a sample signal of the output voltage Vo and superimposes the sample signal with a ripple signal, deriving a sense voltage Vout. A comparator generates a comparison signal PoPeq_S from a comparison made between the sense voltage Vout and a reference voltage Vref2 and sends it to a transmitter. The transmitter produces a control signal Vcontrol for turning on the switching device M1, the control signal Vcontrol is then transferred to the first control chip 21 by the magnetic coupling chip 23. The first control chip 21 employs, for example, an SSR (secondary side regulation) control method with good dynamic response. The first control chip 21 includes a frequency-based on-time control unit configured to produce a turn-off control signal SSR_Vlimit based on a frequency of the control signal Vcontrol. The first control chip 21 further includes a drive generator module configured to receive the turn-off control signal SSR_Vlimi, the control signal Vcontrol and a current sample signal Vcs and produce a switching control signal SSR_Gate which is applied to the control terminal of the switching device M1. In this way, control of an on-time period of the switching device M1, and hence of turn-on and turn-off of the switching device M1, is achieved.

FIG. 3 schematically illustrates communication between the first and second control chips according to another embodiment of the present invention. Referring to FIG. 3, in this embodiment, the control circuit 20 may employ a control method based on an average output voltage. In this embodiment, the second control chip 22 acquires a sense signal in the form of a sense voltage Vout from the output voltage Vo, and an operational amplifier amplifies an error between the sense voltage Vout and the reference voltage Vref2 and outputs an amplified error signal Comp_SSR, the amplified error signal Comp_SSR represents an integral value of the difference between the sense voltage Vout and the reference voltage Vref2. The second control chip 22 also receives the amplified error signal Comp_SSR, and a frequency control module produces a frequency signal SSR_fs from the amplified error signal Comp_SSR, the frequency signal SSR_fs is then sent to a transmitter. Upon receiving the frequency signal SSR_fs, the transmitter generates a control signal Vcontrol for turning on the switching device M1. The control signal Vcontrol is transferred by the magnetic coupling chip 23 to the first control chip 21. The first control chip 21 employs, for example, an SSR (secondary side regulation) control method with good dynamic response. The first control chip 21 includes a frequency-based on-time control unit configured to produce a turn-off control signal SSR Vlimit based on a frequency of the control signal Vcontrol. The first control chip 21 further includes a drive generator module configured to receive the turn-off control signal SSR_Vlimi, the control signal Vcontrol and a current sample signal Vcs and produce a switching control signal SSR_Gate which is applied to the control terminal of the switching device M1. In this way, control of an on-time period of the switching device M1, and hence of turn-on and turn-off of the switching device M1, is achieved. In this embodiment, the control circuit 20 utilizes the frequency control module to adjust the frequency and hence the output voltage Vo to make an average of the sense voltage Vout associated with the output voltage Vo equal to the reference voltage Vref2. For example, when the sense voltage Vout is higher than the reference voltage Vref2, the amplified error signal Comp_SSR is gradually decreased, and hence the frequency output by the frequency control module is gradually decreased. Based on feedback of this, a primary-side turn-on frequency of the high-frequency transformer 13 is decreased, thus reducing the output voltage Vo. That is, negative feedback is provided. Finally, in a steady state, Vout=Vref2.

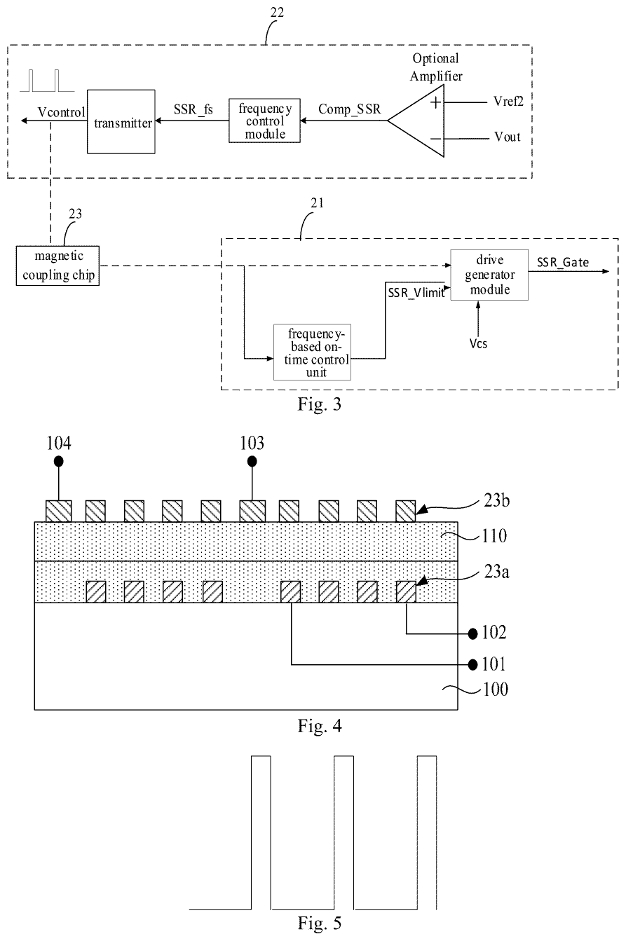

FIG. 4 is a schematic cross-sectional view of the magnetic coupling chip according to an embodiment of the present invention. Referring to FIG. 4, in one example, the magnetic coupling chip 23 includes a semiconductor substrate 100 and first coil conductor 23a and the second coil conductor 23b both provided on the semiconductor substrate 100. The first coil conductor 23a and the second coil conductor 23b provide an electromagnetic inductive communication link through electromagnetic induction between them. Each of the first coil conductor 23a and the second coil conductor 23b may include a metal coil with one, two or more turns (a longitudinal cross-section of the turns is schematically shown in FIG. 4). The first coil conductor 23a may be connected to an external device through a first terminal 101 and a second terminal 102, and the second coil conductor 23b may be connected to an external device through a third terminal 103 and a fourth terminal 104.

Optionally, as shown in FIG. 4, the first coil conductor 23a and the second coil conductor 23b may be piled in a thickness direction of the semiconductor substrate 100, the second coil conductor 23b is located on the side of the first coil conductor 23a away from the semiconductor substrate 100. An insulating layer 110 may be arranged between the first coil conductor 23a and the second coil conductor 23b. In a specific non-limiting example, the first coil conductor 23a and the second coil conductor 23b may be situated in planes at different heights above the semiconductor substrate 100, and the insulating layer 110 may intervene between the first coil conductor 23a and the second coil conductor 23b. In some other embodiments, the first coil conductor 23a and the second coil conductor 23b may be situated in a single plane above the semiconductor substrate 100. The first coil conductor 23a and the second coil conductor 23b may be formed using an integrated circuit process involving depositing metal layers on the semiconductor substrate 100 and etching the metal layers.

For example, the first coil conductor 23a is coupled to the aforementioned first control chip 21, and the second coil conductor 23b is coupled to the aforementioned second control chip 22. One-way or two-way communication may occur between the first control chip 21 and the second control chip 22. For example, when the first control chip 21 transmits, as a signal transmitter, a signal to the second control chip 22, the first coil conductor 23a may transfer the signal to the second coil conductor 23b and the second control chip 22 through a communication link formed by electromagnetic induction. Accordingly, the second control chip 22 serves as a signal receiver. When the second control chip 22 transmits, as a signal transmitter, a signal to the first control chip 21, the second coil conductor 23b may transfer the signal to the first coil conductor 23a and the first control chip 21 through a communication link formed by electromagnetic induction. In this case, the first control chip 21 serves instead as a signal receiver.

FIG. 5 schematically illustrates short pulses according to an embodiment of the present invention. Referring to FIGS. 1 to 5, the magnetic coupling chip 23 may transmit a magnetic coupling transmit signals in the form of short pulses. Specifically, in one example, the second control chip 22 senses the output voltage Vo of the aforementioned switching circuit 10 and is based on the output voltage Vo to control the second control chip 22 to transmit a control signal to the first control chip 21. The control signal may be transmitted in the form of short pulses to the first control chip 21 via the magnetic coupling chip 23. That is, the control signal Vcontrol may be transmitted through the magnetic coupling chip 23 to the first control chip 21 as short pulses (which, for example, make up a square-wave signal with a duty cycle less than 50%).

For example, the control circuit 20 may include one, two or three IC packages each in the form of an independent chip package. Each IC package may include at least one chip, a lead frame which supports the chip and an encapsulation body which covers the chip and part of the lead frame. The lead frame may include one or more conductors. Examples of the conductors may include copper. Each conductor may be generally flat, and its majority may be buried in the encapsulation body. The conductors may define solder features and pins. The solder features are configured for soldering and mounting of a chip and to provide electrical connections with the pins. The lead frame may also function to dissipate heat. The encapsulation body may include, for example, an inorganic or organic insulating material. For example, it may include epoxy resin.

The first control chip 21, the second control chip 22 and the magnetic coupling chip 23 may be discrete chips, or two or three of them may be integrated into a single chip structure. Each chip structure is packaged in one IC package.

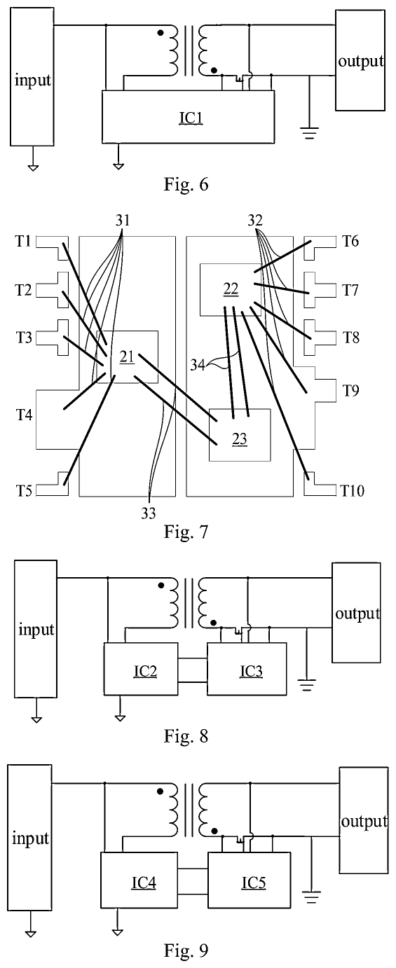

FIG. 6 shows the control circuit 20 consisting of an IC package ICI in one example, in which the structure of the switching circuit 10 is depicted in a simplified form and “Input” and “Output” denote the input and output terminals of the switching circuit 10, respectively. FIG. 7 schematically illustrates wiring of the lead frame, the first control chip 21, the second control chip 22 and the magnetic coupling chip 23 in the IC package ICI of FIG. 6. Referring to FIGS. 6 and 7, in one example, the first control chip 21, the second control chip 22 and the magnetic coupling chip 23 of the control circuit 20 are all integrated in the IC package ICI, and the IC package ICI further includes a lead frame and an encapsulation body (not shown). The lead frame supports the first control chip 21, the second control chip 22 and the magnetic coupling chip 23 and has multiple pins (e.g., T1-T10 of FIG. 7). The first control chip 21 is coupled to some of the pins (e.g., T1-T5 of FIG. 7) by first metal bond wires 31, and the second control chip 22 is coupled to the remaining pins (e.g., T6-T10 of FIG. 7) by second metal bond wires 32. Moreover, the first control chip 21 is coupled to the magnetic coupling chip 23 by the third metal bond wires 33, and the second control chip 22 is coupled to the magnetic coupling chip 23 by the fourth metal bond wires 34. It is to be noted that the number of metal bond wires shown in FIG. 7 is only for illustration, and an appropriate number of metal bond wires may be provided as required by the wiring of the first control chip 21 and the second control chip 22 to the magnetic coupling chip 23. In this embodiment, in the IC package ICI, the encapsulation body covers the first control chip 21, the second control chip 22, the magnetic coupling chip 23 and part of the lead frame, with the pins on the lead frame being exposed.

FIG. 8 shows the control circuit 20 consisting of IC packages IC2 and IC3 in another example, in which the structure of the switching circuit 10 is depicted in a simplified form and “Input” and “Output” denote the input and output terminals of the switching circuit 10, respectively. Referring to FIG. 8, in this example, the first control chip 21 and the magnetic coupling chip 23 of the control circuit 20 are integrated in one of the IC packages (IC2), while the second control chip 22 is integrated in the other of the IC packages (IC3). In this example, in the IC package IC2, the first control chip 21 and the magnetic coupling chip 23 may be, for example, standalone dies, which are soldered and mounted on a single lead frame and connected by metal bond wires. The first control chip 21 and the magnetic coupling chip 23 may be coupled to pins of the lead frame by metal bond wires, and an encapsulation body may cover the first control chip 21, the magnetic coupling chip 23 and part of the lead frame in the IC package IC2, with the pins on the lead frame being exposed to allow external connection of the first control chip 21 and the magnetic coupling chip 23 for communication. In another example, instead of being standalone dies, the first control chip 21 and the magnetic coupling chip 23 may be both integrated onto the semiconductor substrate 100 using an IC process and connected with interconnects formed on the semiconductor substrate 100. The second control chip 22 is mounted on another lead frame and may be coupled to pins on the lead frame by metal bond wires. In the IC package IC3, an encapsulation body may cover the second control chip 22 and part of the lead frame, with the pins on the lead frame being exposed to allow external connection of the second control chip 22 for communication.

FIG. 9 shows the control circuit 20 consisting of IC packages IC4 and IC5 in yet another example, in which the structure of the switching circuit 10 is depicted in a simplified form and “Input” and “Output” denote the input and output terminals of the switching circuit 10, respectively. Referring to FIG. 9, in this example, the first control chip 21 of the control circuit 20 is integrated in one of the IC packages (IC4), while the second control chip 22 and the magnetic coupling chip 23 are integrated in the other of the IC packages (IC5). In this example, the first control chip 21 may be a standalone die, which is mounted on a lead frame and may be coupled to pins on the lead frame by metal bond wires. In the IC package IC4, an encapsulation body may cover the first control chip 21 and part of the lead frame, with the pins on the lead frame being exposed to allow external connection of the first control chip 21 for communication. In the IC package IC5, the second control chip 22 and the magnetic coupling chip 23 may be soldered and mounted on a lead frame and connected by metal bond wires. The second control chip 22 and the magnetic coupling chip 23 may be coupled to pins on the lead frame by metal bond wires, and an encapsulation body may cover the second control chip 22, the magnetic coupling chip 23 and part of the lead frame in the IC package IC5, with the pins on the lead frame being exposed to allow external connection of the second control chip 22 and the magnetic coupling chip 23 for communication. However, the present invention is not so limited, and in a further example, instead of being standalone dies, the second control chip 22 and the magnetic coupling chip 23 may be both integrated onto the semiconductor substrate 100 using an IC process and connected with interconnects formed on the semiconductor substrate 100.

In the switched-mode power converter of the present invention, the control circuit 20 includes the first control chip 21, the second control chip 22 and the magnetic coupling chip 23. The magnetic coupling chip 23 is coupled to both the first control chip 21 and the second control chip 22. The magnetic coupling chip 23 provides a galvanically isolated communication link between the first control chip 21 and the second control chip 22. With the aid of the second control chip 22 and the magnetic coupling chip 23, the control circuit 20 can provide a feedback signal to the first control chip 21 and thereby act on turn-on and turn-off of the switching device MI in the switching circuit 10. In this way, desirable output and isolation performance can be achieved. Since the first control chip 21, the second control chip 22 and the magnetic coupling chip 23 can be integrated at a high degree of integration, the switched-mode power converter can have a high degree of integration, reduced size and lower cost.

The foregoing description is merely that of several preferred embodiments of this disclosure and is not intended to limit the scope of the claims thereof in any way. Any person of skill in the art may make various possible variations and changes to the disclosed embodiments in light of the methodologies and teachings disclosed hereinabove, without departing from the spirit and scope of the invention. Accordingly, any and all such simple variations, equivalent alternatives and modifications made to the foregoing embodiments based on the essence of this disclosure without departing from the scope of the embodiments are intended to fall within the scope of protection of the disclosure.

1. A switched-mode power converter comprising a switching circuit and a control circuit, the switching circuit comprising a switching device, the switching device configured to convert an input voltage into an output voltage by turning on and off the switching device, the control circuit comprising:
a first control chip coupled to a control terminal of the switching device;
a second control chip coupled to an output terminal of the switching circuit; and
a magnetic coupling chip coupled to both the first control chip and the second control chip, the magnetic coupling chip configured to provide a galvanically isolated communication link between the first control chip and the second control chip.

2. The switched-mode power converter of claim 1, wherein the magnetic coupling chip is integrated, together with at least one of the first and second control chips, into an integrated circuit (IC) package.

3. The switched-mode power converter of claim 2, wherein the first control chip, the second control chip and the magnetic coupling chip are all integrated into the IC package.

4. The switched-mode power converter of claim 3, wherein, in addition to the first control chip, the second control chip and the magnetic coupling chip, the IC package further comprises:
a lead frame supporting the first control chip, the second control chip and the magnetic coupling chip and comprising a plurality of pins, some of which are coupled to the first control chip, and the others of which are coupled to the second control chip, wherein the first control chip is coupled to the magnetic coupling chip by first metal bond wires, the second control chip is coupled to the magnetic coupling chip by second metal bond wires; and
an encapsulation body, which covers the first control chip, the second control chip, the magnetic coupling chip and part of the lead frame, with the plurality of pins being exposed.

5. The switched-mode power converter of claim 2, wherein the first control chip and the magnetic coupling chip are integrated into the IC package, and the second control chip is integrated into another IC package.

6. The switched-mode power converter of claim 2, wherein the second control chip and the magnetic coupling chip are integrated into the IC package, and the first control chip is integrated into another IC package.

7. The switched-mode power converter of claim 1, wherein the magnetic coupling chip comprises a semiconductor substrate and first and second coil conductors both provided on the semiconductor substrate, the first and second coil conductors providing an electromagnetic inductive communication link therebetween, the first coil conductor coupled to the first control chip, the second coil conductor coupled to the second control chip.

8. The switched-mode power converter of claim 7, wherein the first and second coil conductors are located in planes at different heights above the semiconductor substrate and are spaced apart by an insulating layer disposed therebetween.

9. The switched-mode power converter of claim 7, wherein the first and second coil conductors are located in a single plane on the semiconductor substrate.

10. The switched-mode power converter of claim 1, wherein the second control chip senses the output voltage of the switching circuit and is based on the output voltage to control the second control chip to send a control signal to the first control chip, wherein the control signal is sent to the first control chip via the magnetic coupling chip.

11. The switched-mode power converter of claim 10, wherein the control signal is in the form of short pulses.

12. The switched-mode power converter of claim 1, wherein the switching circuit comprises a high-frequency transformer for energy transfer, wherein the first control chip is coupled to a primary-side input terminal of the high-frequency transformer by the switching device.

13. The switched-mode power converter of claim 1, wherein the switching circuit is an isolated or non-isolated AC/DC converter; or the switching circuit is an isolated or non-isolated DC/DC converter.

14. The switched-mode power converter of claim 10, wherein the second control chip further comprises a transmitter configured to produce the control signal for turning on the switching device.

15. The switched-mode power converter of claim 14, wherein the first control chip comprises a frequency-based on-time control unit configured to produce a turn-off control signal based on a frequency of the control signal.

16. The switched-mode power converter of claim 15, wherein the first control chip further comprises a drive generator module configured to receive the turn-off control signal, the control signal and a current sample signal and produce a switching control signal which is applied to the control terminal of the switching device.
